(19) United States
(12) Patent Application Publication
(10) Pub. No.: US 2009/0200264 A1
(43) Pub. Date: Aug. 13, 2009

(54) Method For Making A Spin Valve Nano-Contact Entering The Constituition Of A Radio-Frequency Oscillator

(75) Inventors: Marie-Claire Cyrille, Sinard (FR); Fabienne Ponthenier, Champagnier (FR)

Correspondence Address: MARJAMA MULDOON BLASIAK & SULLIVAN LLP, 250 SOUTH CLINTON STREET, SUITE 300, SYRACUSE, NY, 13202, US

(73) Assignee: Commissariat A L'Energie Atomique, Paris (FR)

(21) Appl. No.: 12/356,237

(22) Filed: Jan. 20, 2009

(30) Foreign Application Priority Data
Feb. 13, 2008 (FR) 0850906

(51) Int. Cl. B44C 1/22; C23C 14/34

(52) U.S. Cl. 216/22; 216/51; 204/192.11

(57) ABSTRACT

This method for making a nano-contact on a spin valve for the purposes of constituting a radio-frequency oscillator, consists, after deposition of the magnetic stack constituting the spin valve on a lower electrode in depositing on said magnetic stack a metal layer known as a “barrier” layer; in depositing on this “barrier” layer another metal layer; in depositing locally on this metal layer a hard mask; in subjecting the assembly to a first selective etching step of the metal layer constituting the injector through the hard mask, said metal layer being over-etched during this step under the hard mask in order to give the nano-contact its final dimension; in subjecting the assembly so obtained to a second selective etching step, able to induce the partial removal of the barrier layer and of the magnetic stack substantially on the periphery of the hard mask; in encapsulating the assembly obtained in a dielectric; in planarizing the encapsulated assembly so obtained until ending plumb with the residual layer of the hard mask or of the injector; and finally in putting the conductive upper electrode in place.

### CROSS REFERENCE To RELATED APPLICATIONS

This application claims priority under 35 U.S.C. §119 from French Patent Application No. 0850906 filed on Feb. 13, 2008 in the French Patent Office, the entire disclosure of which is incorporated herein by reference

### FIELD OF THE INVENTION

The invention belongs to the field of radio-frequency oscillators that employ spin valves.

It is more particularly targeted at the formation of nano-contacts including a metal injector that comes into contact with the spin valve, and is intended to allow said spin valve to be subjected to an electric excitation current in order to generate an oscillation of the magnetic moment of one of the magnetic layers of which it is constituted.

### BACKGROUND OF THE INVENTION

Radio-frequency oscillators are intended to operate in high frequency ranges, typically between a GHz and several tens of GHz.

To meet the demands arising from the development of portable, mobile (cell) telephones, in particular, as well as from the saturation of the frequency bands assigned to telecommunications, a proposal has been made to replace the static allocation of said frequency bands with a dynamic allocation. This principle rests on the capacity to analyze the frequency spectrum and identify free frequency bands, in order to be able to use them. This is then known as opportunistic radio.

However, in order to apply the principle in respect of the dynamic allocation of frequencies, the devices that use them must be provided with very wide band oscillators, and furthermore be highly effective in phase noise, and therefore have a high quality coefficient Q=f/Δf.

One technical solution suitable for meeting these demands lies in using radio-frequency oscillators with spintronics. With oscillators of this kind, a wide frequency band is provided with a high quality factor Q, as well as easy frequency accordability and a relatively simple architecture is employed.

Spintronics exploits electron spin as an additional degree of freedom, in order to generate new effects. The spin polarization of an electric current causes magneto-resistive phenomena in the magnetic multi-layers, such as giant magneto-resistance or tunnel magneto-resistance.

It has been shown that a spin polarized current passed through a thin magnetic layer could induce a reversal of its magnetization in the absence of any external magnetic field. The spin polarized current may also generate sustained magnetic excitations, also referred to as oscillations. The use of the effect of generating sustained magnetic excitations in a magneto-resistive device allows this effect to be converted into an electric resistance modulation that can be used directly in electronic circuits, and is therefore, as a result, able to intervene directly at frequency level.

The document U.S. Pat. No. 5,695,864 describes various developments that employ the physical principle mentioned above, and in particular describe the precession of the magnetization of a magnetic layer passed through by a spin polarized electric current. Two types of stacks of magnetic layers able to constitute such a radio-frequency oscillator have been shown in FIGS. 1 and 2. These stacks are inserted between two current inputs, whereof the contact with the two end layers is for example made out of copper or gold.

The layer 1 of this stack, known as the “trapped layer”, is magnetized in a fixed direction. It may be a single layer, with a typical thickness of between 5 and 100 nanometres, made of cobalt for example, of an alloy CoFe or NiFe. This trapped layer 1 may be single or synthetic. It basically fulfills the function of polarizer. As such, the electric current electrons passing through the layers constituting the magneto-resistive device perpendicular to their plane, reflected or transmitted by the polarizer, are polarized with a direction of spin parallel to the magnetization that the layer 1 has at the interface opposite the one in contact with an anti-ferromagnetic layer 4, with which it is associated, and intended to fix the direction of its magnetization.

Additionally, this layer 1 receives on its face opposite the face receiving the anti-ferromagnetic layer 4 another layer 3 functioning as spacer.

This layer 3 is metallic in nature, typically a layer of copper from 3 to 10 nanometres thick, or is constituted by a fine insulating layer of the aluminum oxide type, with a typical thickness of between 0.5 and 1.5 nanometres, or of magnesium oxide, with a typical thickness of between 0.5 and 3 nanometres.

A layer 2, generally narrower than the layer 1, is put in place on the other side of the spacer 3. This layer 2 may also be coupled with an anti-ferromagnetic layer 6 added to it on its face opposite the interface of the layer 2 with the spacer 3. This layer 6 is for example constituted of an alloy such as Ir₈₀Mn₂₀, of FeMn or of PtMn.

To advantage, the material used in respect of the layer 2 has a good exchange stiffness constant. This material is typically a 3d metal, and more particularly cobalt or cobalt-rich alloys.

The magneto-resistive stacks employed in making such oscillators use stacks produced in two different ways: so-called “pillar” stacks: all the layers are etched to make a pillar with a diameter of about 50 to 100 nanometres; so-called “contact point” stacks: in a stack of this kind, the active layers (layer 1, layer 2, layer 3, or even the layers of anti-ferromagnetic material) are not etched with nanometric patterns or if they are, are then manufactured using very large patterns (close to a square micrometre); a very close metal contact is produced, typically 50 nanometres, above the layer 2 or the anti-ferromagnetic layer associated with it, by means of a nanotip that is external (for example tip of an atomic force microscope or injector) or internal, a lithographed pillar.

Nano-contacts are preferred when spin valves are employed, as they produce better defined radio-frequency emissions, and particularly finer radio-frequency emissions. Indeed, it has been possible to observe a reduction in the width of RF emission lines that is attributed to the minimization of the edge effects due to the manufacturing process, and to the increase in the volume of the free layers.

Making nano-contacts generally involves manufacturing a metal nano-injector above the spin valve, or a nano-hole made in a dielectric, with is subsequently filled with metal. The spin valve must additionally be patterned to form elementary components. Making these nano-contacts therefore involves at least two lithography steps, namely one to make a nano-contact and one to make the spin valve with the alignment constraints between the nano-contact and the spin valve, and also two distinct etching sequences and two distinct resin removal or stripping sequences.

Through this, the implementation of nano-contacts of this kind significantly complicates production of the oscillator, driving up costs and increasing the length of the process.

The objective targeted by the present invention is to simplify the production of such nano-contacts.

### SUMMARY OF THE INVENTION

The inventive method for making a nano-contact on a spin valve for the purpose of forming a radio-frequency oscillator consists, after deposition, by cathode sputtering or by ion gun for example, of the magnetic stack constituting the spin valve on a lower electrode: in depositing on said magnetic stack a metal layer known as a “barrier” layer, intended to halt the etching step, that occurs subsequently; in depositing on this “barrier” layer another metal layer intended subsequently to constitute the injector of a nano-contact strictly speaking; in depositing locally on this metal layer a hard mask, intended to confine the subjacent layers; in subjecting the assembly to a first selective etching step of the metal layer constituting the injector through the hard mask, said “barrier” layer acting as a barrier to this etching step, said metal layer being over-etched during this step under the hard mask so as to give the nano-contact its final shape; in subjecting the assembly so obtained to a second selective etching step able to induce the partial removal of said “barrier” layer and of the magnetic stack substantially on the periphery of the hard mask; in encapsulating the assembly so obtained in a dielectric; in planarizing the encapsulated assembly so obtained until ending plumb with the residual layer of the hard mask or the injector; and finally in putting the conductive upper electrode in place.

In other words, the invention consists in combining into a single photolithography sequence the nano-manufacture of the injector and that of the magnetic contact plate constituting the spin valve, such that the injector is thus automatically aligned on said magnetic contact plate.

As can therefore be initially and basically imagined the alignment constraints, occurring when two photolithography steps are implemented as in the prior art nano-contact production method, are eliminated.

Another end result is a drop in the number of manufacturing steps, leading to a saving of time and a reduction in costs.

Lastly, the inventive method means that effective control is achieved over the dimensions when making the magnetic contact plates, typically less than 100 nanometres, or even less than 50 nanometres, where the use of photolithography makes dimension control difficult.

According to the invention, the etching barrier layer is deposited by cathode sputtering or ion gun. This barrier layer is typically constituted by a layer of aluminum from 10 to 20 nanometres thick.

According to the invention, the metal layer suitable for constituting the injector itself is also deposited by cathode sputtering or ion gun, the metal constituting said injector being tantalum, molybdenum or titanium.

According to the invention, a layer of resin is deposited locally on the layer constituting the hard mask and the assembly so obtained is subjected to a photolithography step.

Additionally, the first selective etching step is for example implemented by reactive ion etching.

Still according to the invention, the second selective etching step is for example implemented by ion beam etching or IBE.

Still according to the invention, the layer for constituting the hard mask is deposited by direct current cathode sputtering, the hard mask being typically constituted by a layer of chromium, ruthenium or aluminum from 10 to 50 nanometres thick or an oxide layer, for example Al₂O₃ or SiO₂.

The photolithography step is implemented to advantage by deep ultraviolet or DUV, or electronics so as to define contact plates with dimensions of typically between 100 and 300 nanometres.

According to the invention, the residual layer of the hard mask and the diameter of the injector respectively are sized by selecting chlorination chemistry for the hard mask and fluorination chemistry, type SF₆ or CHF₃ or CF₄ for the injector, further determined by the duration of the etching. The etching barrier layer is attacked by IBE etching, as is the subjacent magnetic stack.

According to the invention, the encapsulation by dielectric is implemented to advantage in two steps: a first step using the atomic layer deposition or ALD technique, and then a second step by deposition by cathode sputtering or ion gun.

The first deposition step, implemented by ALD gives, through its highly conformal nature, conformance in shape to the surface projections and ensures the deposition of a very high quality dielectric. The second deposition step, by sputtering, is used to complete the encapsulation in shorter time.

The dielectric material is typically constituted by alumina, Al₂O₃ or silica SiO₂.

According to the invention, the magnetic stack constituting the spin valve includes: a first magnetic layer known as a “trapped layer,” whereof the magnetization is of fixed direction, a second magnetic layer, an nonmagnetic layer, interposed between the two previous layers, intended to function as a spacer, and intended to decouple said layers magnetically.

To advantage, said second magnetic layer is constituted by a single layer with which an anti-ferromagnetic layer is associated, the latter being placed on the face of said second layer opposite the nonmagnetic layer functioning as spacer, the material constituting the anti-ferromagnetic layer being selected from the group that includes the following alloys: Ir₂₀Mn₈₀, FeMn and PtMn. As an alternative, the second magnetic layer may be a synthetic layer, coupled or not coupled to an anti-ferromagnetic layer.

To advantage, said first magnetic layer known as the “trapped” layer, functioning as polarizer, is constituted by a single layer, with the trapping provided by the association with an anti-ferromagnetic layer, particularly made out of IrMn or PtMn, added to its face opposite to the interface of said layer with the nonmagnetic layer.

### BRIEF DESCRIPTION OF THE DRAWINGS

The way in which the invention may be embodied, and the advantages arising therefrom, will emerge better from the following embodiment example, given by way of example and non-restrictively, supported by the appended figures.

FIGS. 1 and 2 are, as already said, diagrammatic representations of a radio-frequency oscillator in accordance with the prior art.

FIGS. 3A to 3G are intended to show the different steps in the inventive method.

### DETAILED DESCRIPTION OF THE INVENTION

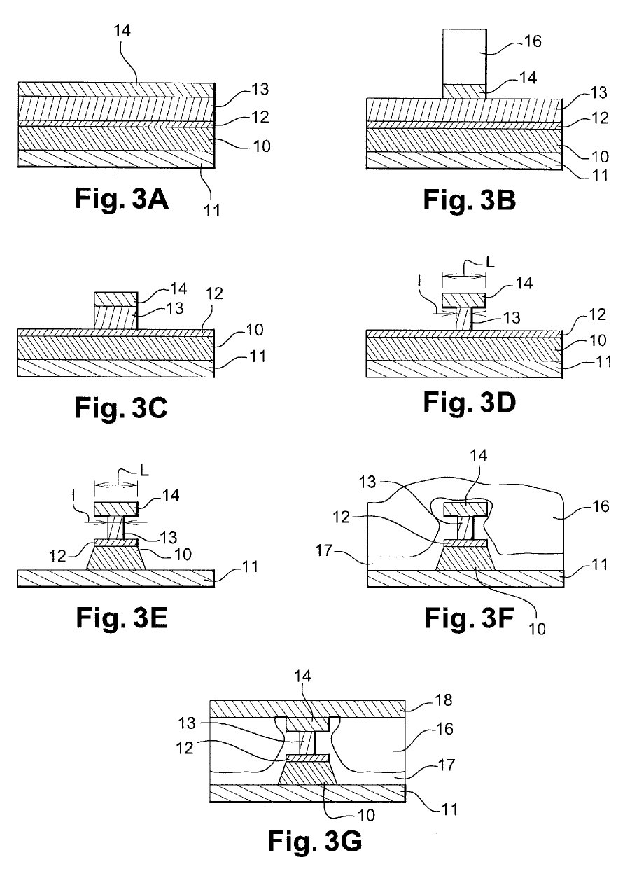

The different steps in the method for producing a nano-contact in accordance with the invention have therefore been shown in relation to FIGS. 3A to 3G.

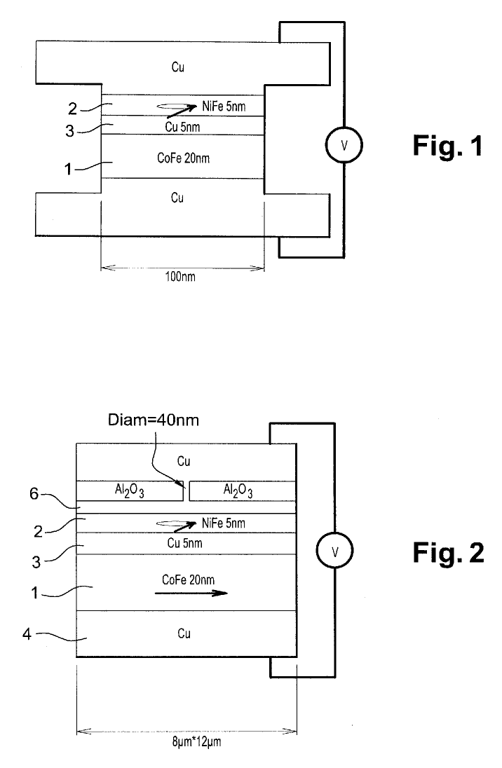

At step 3A, it is assumed that the magnetic stack 10 of the type described in relation to FIGS. 1 and 2 has already been deposited on the lower electrode 11. This deposition may have been carried out by cathode sputtering or by ion gun for example.

The first step is to deposit on the stack 10 a layer 12 of a metal material, typically aluminum, intended to oppose the etching action that occurs subsequently, thereby offering temporary protection to the magnetic stack 10 during said etching step.

This “barrier” layer 12 is typically made of aluminum and produced by cathode sputtering or by ion gun and is between 5 and 20 nanometres thick, and for example 10 nanometres.

After deposition of said layer, the next step is to deposit a metal layer 13, intended to constitute the oscillator nano-contact injector, i.e. through which the spin polarized current will pass.

This layer is also deposited by cathode sputtering or by ion gun.

The metal employed is typically constituted by tantalum, molybdenum, tungsten or titanium. The thickness of this layer is between 50 and 200 nanometres.

Lastly, onto this layer 13 is deposited a localized hard mask 14, intended to act as a mask when etching the subjacent layers. To this end, it is possible, as shown in FIG. 3A, to deposit a continuous layer 14, for example of chromium or ruthenium or aluminum, which is then etched. It is thus possible to deposit on the layer 14 a resin 15 which is confined plumb with what will act as a base for the injector by subjecting it to a step of deep ultra-violet or electron beam photolithography. Resin contact plates are thus obtained, with a typical diameter of between 100 and 300 nanometres.

These contact plates are then used to selectively etch the layer 14 (FIG. 3B) thereby forming the hard mask. Provision may be made for a step of removing the resin 15 at this stage.

The next step is a first etching of the layer 13 constituting the injector through the hard mask 14 so as to give this metal layer 13 its final dimensions. To this end, the first stage may be reactive ion etching (RIE) of the chromium constituting the hard mask by chlorination chemistry (for example using Cl₂ or HBr/Cl₂), reducing the thickness of this layer 14. Then, the next stage (FIG. 3C) is RIE etching of the metal layer 13 by fluorination chemistry SF₆ or CHF₃ or CF₄ with selective stopping on the barrier layer 12 functioning as the etching barrier layer.

RIE etching is continued, as shown in FIG. 3D, until lateral over-etching of the metal layer 13 is obtained, in order to reduce its lateral dimensions relative to the hard mask 14, thereby leading to the required injector dimension. To this end, action is taken in terms of etching time. The etching time may typically be increased by 20 to 50% relative to the time needed to reach the barrier layer 12.

At the step shown in FIG. 3E, a second etching is undertaken, for example ion beam etching or IBE, through the hard mask 14, in order to remove on the one hand, the etching barrier layer 12 located outside the area located plumb with the hard mask 14, and on the other hand, the magnetic stack 10 located outside this same area. This IBE etching may be applied using Argon or Xenon gas, with an angle of incidence of between 5 and 50 degrees.

The next step is to encapsulate the assembly arising out of this last step (FIG. 3F). This encapsulation is performed, by means of a dielectric material, of the silica or alumina type. This encapsulation may be performed by physical vapour deposition or PVD.

To advantage, this encapsulation is implemented on two steps: a first step, implemented by atomic layer deposition 17 (ALD) with a typical thickness of between 30 and 60 nanometres; and then a second step, implemented by cathode sputtering or by ion gun 16 with a thickness of between 100 and 300 nanometres ALD deposition has the advantage of being highly conformal, which means it conforms perfectly in shape to the projections on the structure obtained in FIG. 3E and particularly the overhang under the mask 14 at injector level 13. This deposition is then completed by faster deposition by cathode sputtering or by ion gun. The end result is the assembly shown in FIG. 3F.

The assembly so obtained is then subjected to a step of planarization by chemical mechanical polishing or CMP until the nano-contact plate 14 is obtained so as then to allow the deposition of the upper electrode 18.

In this case, the nano-contact plate must be electrically conductive in order to provide the contact between the upper electrode 18 and the injector 13.

As an alternative, it is possible to continue with planarization until the injector 13 is reached. In this case, the nano-contact plate 14 is removed at this step, a wider choice of material is then possible for the hard mask 14, particularly insulating materials like SiO₂ or Al₂O₃.

As may easily be imagined, because of the inventive method, the alignment constraints are eliminated since the injector 13 is automatically aligned with the magnetic stack 10.

What is more, it is possible by means of the inventive method to end up with nano-contact plates that have reduced dimensions, typically less than 100 nanometres, or even less than 50 nanometres, and are suitable for optimizing the operating conditions of the radio-frequency oscillator arising therefrom.

We claim:

1. A method for making a nano-contact on a spin valve for the purpose of constituting a radio-frequency oscillator, the method consisting essentially of, after deposition of a magnetic stack constituting the spin valve on a lower electrode:
depositing on said magnetic stack a metal layer known as an etching “barrier” layer, intended to halt the etching step, that occurs subsequently;
depositing onto this “barrier” layer another metal layer intended subsequently to constitute an injector of a nano-contact;
depositing locally on this metal layer a hard mask intended to confine the etching of the subjacent layers;
subjecting the assembly to a first selective etching step of the metal layer constituting the injector through the hard mask, the “barrier” layer acting to halt this etching step, said metal layer being over-etched during this step under the hard mask in order to give the nano-contact its final dimension;
subjecting the assembly so obtained to a second selective etching step, able to induce the partial removal of the barrier layer and of the magnetic stack substantially on the periphery of the hard mask;
encapsulating the assembly obtained in a dielectric;
planarizing the encapsulated assembly so obtained until ending plumb with the residual layer of the hard mask or of the injector; and
finally putting a conductive upper electrode in place.

2. The method for making a nano-contact on a spin valve as claimed in claim 1, wherein the etching “barrier” layer is deposited by cathode sputtering or by ion gun.

3. The method for making a nano-contact on a spin valve as claimed in claim 1, wherein the etching “barrier” layer is constituted by a layer of aluminum from 5 to 20 nanometres thick.

4. The method for making a nano-contact on a spin valve as claimed in claim 1, wherein the metal layer intended to constitute the injector is deposited by cathode sputtering or by ion gun.

5. A method for making a nano-contact on a spin valve for the purpose of constituting a radio-frequency oscillator, consisting essentially of, after deposition of a magnetic stack constituting the spin valve on a lower electrode:
depositing on said magnetic stack a metal layer known as an etching “barrier” layer, intended to halt the etching step, that occurs subsequently;
depositing onto this “barrier” layer another metal layer intended subsequently to constitute an injector of a nano-contact;
depositing locally on this metal layer a hard mask intended to confine the etching of the subjacent layers;
depositing a layer of resin locally on the layer constituting the hard mask, the assembly so obtained being subjected to a photolithography step;
subjecting the assembly to a first selective etching step of the metal layer constituting the injector through the hard mask, the “barrier” layer acting to halt this etching step, said metal layer being over-etched during this step under the hard mask in order to give the nano-contact its final dimension;
subjecting the assembly so obtained to a second selective etching step, able to induce the partial removal of the barrier layer and of the magnetic stack substantially on the periphery of the hard mask;
encapsulating the assembly obtained in a dielectric;
planarizing the encapsulated assembly so obtained until ending plumb with the residual layer of the hard mask or of the injector; and
finally putting a conductive upper electrode in place.

6. The method for making a nano-contact on a spin valve as claimed in claim 1, wherein the first selective etching step is implemented by reactive ion etching.

7. The method for making a nano-contact on a spin valve as claimed in claim 1, wherein the second selective etching step is implemented by ion beam.

8. The method for making a nano-contact on a spin valve as claimed in claim 1, wherein the metal constituting the injector is selected from the group consisting of tantalum, molybdenum, tungsten and titanium.

9. The method for making a nano-contact on a spin valve as claimed in claim 1, wherein the layer intended to constitute the hard mask is deposited by direct current cathode sputtering.

10. The method for making a nano-contact on a spin valve as claimed in claim 1, wherein the layer constituting the hard mask is constituted by a material selected from the group consisting of chromium, aluminum, ruthenium, silica (SiO₂) and alumina (Al₂O₃).

11. The method for making a nano-contact on a spin valve as claimed in claim 1, wherein the layer constituting the hard mask is between 10 and 50 nanometres thick.

12. The method for making a nano-contact on a spin valve as claimed in claim 1, wherein the injector diameter is sized by fluorination chemistry, of the type SF₆ or CHF₃ or CF₄ for the injector during an etching step, the diameter of said injector being further adjusted by the duration of said etching.

13. The method for making a nano-contact on a spin valve as claimed in claim 1, wherein the encapsulation by dielectric phase is implemented in two steps:
a first step by atomic layer deposition, and
then a second step by cathode sputtering or ion gun deposition.

14. The method for making a nano-contact on a spin valve as claimed in claim 1, wherein the dielectric encapsulation material is selected from the group consisting of alumina and silica.

15. The method for making a nano-contact on a spin valve as claimed in claim 1, wherein the magnetic stack includes:
a first magnetic layer known as a “trapped layer”, whereof the magnetization is of fixed direction,
a second magnetic layer,
a nonmagnetic layer interposed between the two previous layers, intended to function as spacer, and intended to decouple said layers magnetically.

16. The method for making a nano-contact on a spin valve as claimed in claim 15, wherein the second magnetic layer is constituted by a single layer with which is associated an anti-ferromagnetic layer, the latter being placed on the face of said layer opposite the nonmagnetic layer functioning as spacer, the material constituting the anti-ferromagnetic layer being selected from the group consisting of: Ir₂₀Mn₈₀, FeMn and PtMn.

17. The method for making a nano-contact on a spin valve as claimed in claim 15, wherein the first magnetic layer known as the trapped layer, functioning as polarizer, is constituted by a single layer, with the trapping being ensured by the association with an anti-ferromagnetic layer, particularly made out of IrMn or PtMn, added to its face opposite the interface of said layer with the nonmagnetic layer.
